(19) United States
(12) Patent Application Publication
(10) Pub. No.: US 2012/0326264 A1
(43) Pub. Date: Dec. 27, 2012

(54) METHOD OF FABRICATING SEMICONDUCTOR DEVICE, AND SEMICONDUCTOR DEVICE

(75) Inventors: Yasumori Fukushima, Osaka-shi (JP); Yutaka Takafuji, Osaka-shi (JP); Kenshi Tada, Osaka-shi (JP)

(73) Assignee: SHARP KABUSHIKI KAISHA, Osaka-shi, Osaka (JP)

(21) Appl. No.: 13/497,807

(22) PCT Filed: May 18, 2010
(86) PCT No.: PCT/JP2010/058323

§ 371 Date: Mar. 23, 2012

(30) Foreign Application Priority Data
Sep. 25, 2009 (JP) 2009-221060

(51) Int. Cl. H01L 21/58; H01L 25/00

(52) U.S. Cl. 257/499; 438/107; 257/E25.001; 257/E21.505

(57) ABSTRACT

A method of fabricating a semiconductor device of the present invention includes the steps of forming a single crystal semiconductor device, attaching the single crystal semiconductor device on a substrate, forming a TFT on a glass substrate, and electrically connecting the single crystal semiconductor device and the TFT. In the step of forming a single crystal semiconductor device, an alignment mark is provided at the single crystal semiconductor device. In the step of attaching a single crystal semiconductor device, the single crystal semiconductor device is positioned and attached on the glass substrate based on the machining accuracy of an attachment device. In the step of forming a TFT, the TFT is positioned and provided on the glass substrate based on the alignment mark provided at the single crystal semiconductor device.

### TECHNICAL FIELD

The present invention relates to a method of fabricating a semiconductor device formed of an integrated circuit by electrical connection of a single crystal semiconductor device identified as a circuit element attached on a substrate and a structure identified as a circuit element formed on the substrate, and a semiconductor device fabricated according to the method. More specifically, the present invention relates to a method of fabricating a semiconductor device suitable for usage in a display device such as a liquid crystal display device and an organic electroluminescence display device, and a semiconductor device fabricated according to the method.

### BACKGROUND ART

In the field of semiconductor devices, the SOI (Silicon On Insulator) technique to form a thin single crystal silicon layer at the surface of an insulation layer is conventionally known. The semiconductor device formed through the SOI technique is directed to reducing the parasitic capacitance and maintaining the insulation resistance at a high level by forming a transistor or the like identified as a circuit element at the aforementioned thin single crystal silicon layer, allowing high performance and large scale integration of the transistor and the like. For the aforementioned insulation layer, a silicon oxide film, for example, is suitable. With regard to a semiconductor device formed through the SOI technique, the thickness of the single crystal silicon layer is preferably made as thin as possible in order to further improve the operation speed and further reduce the parasitic capacitance of the transistor and the like.

The method of enabling the SOI technique includes various methods such as utilizing mechanical polishing, chemical mechanical polishing (CMP), employing porous silicon for the substrate, and the like. As an example of the SOI technique utilizing hydrogen introduction, Bruel proposes a smart cut method including the steps of forming a detachable hydrogen introduction layer by introducing hydrogen into a single crystal semiconductor substrate, attaching the single crystal semiconductor substrate with the formed hydrogen introduction layer to another substrate, applying thermal treatment to detach a portion of the single crystal semiconductor substrate along the hydrogen introduction layer for separation, and transferring the thinned single crystal semiconductor substrate to the additional substrate (refer to Electronics Letters, Vol. 31, No. 14, 1995, p. 1201 (Non-Patent Literature 1), JJAP, Vol. 36, 1997, p. 1636 (Non-Patent Literature 2)).

By a forming a transistor or the like identified as a circuit element at the thinned single crystal semiconductor substrate in such a single crystal semiconductor device formed by the smart cut method, the parasitic capacitance is reduced significantly and the insulation resistance can be maintained at a drastically high level, allowing significant increase in the performance and scale of integration of the transistor and the like.

As a method of transferring a thinned single crystal semiconductor substrate to an additional substrate, there is proposed a method including the steps of forming in advance a flattened hydrophilic oxide film on the face of the single crystal semiconductor substrate and the face of the additional substrate that will be attached to each other, and then attaching the oxide films together, whereby the single crystal semiconductor substrate and additional substrate are attached to each other.

Regarding the approach of transferring a thinned single crystal semiconductor substrate to an additional substrate, application of the relevant technique to fabricate a semiconductor device formed of an integrated circuit by electrically connecting a single crystal semiconductor device identified as a circuit element attached to a substrate and a structure identified as a circuit element formed on the substrate is disclosed in, for example, Japanese Patent Laying-Open No. 2008-66566 (Patent Literature 1) and Japanese Patent Laying-Open No. 2008-147445 (Patent Literature 2).

The publications of Japanese Patent Laying-Open No. 2008-66566 and Japanese Patent Laying-Open No. 2008-147445 disclose a specific method of fabricating a semiconductor device formed of an integrated circuit by electrically connecting a single crystal semiconductor device identified as a circuit element attached to a substrate and a structure identified as a circuit element formed on the substrate, as set forth below.

First, a single crystal semiconductor element such as an MOS (Metal Oxide Semiconductor) transistor is formed on a single crystal semiconductor substrate to obtain a single crystal semiconductor device. Hydrogen is introduced into this single crystal semiconductor device to form a hydrogen-introduced layer at the single crystal semiconductor substrate. The single crystal semiconductor device including the single crystal semiconductor substrate with the hydrogen-introduced layer formed is attached to an additional substrate, followed by thermal treatment, whereby the single crystal semiconductor substrate is detached along the hydrogen-introduced layer to be separated. Accordingly, a single crystal semiconductor device having a thinned single crystal semiconductor substrate is transferred to the aforementioned additional substrate.

Then, the single crystal semiconductor device having wiring and the like formed is attached to a glass substrate. By removing the additional substrate from the single crystal semiconductor device attached to the glass substrate, the single crystal semiconductor device is transferred to the glass substrate. Then, a TFT (Thin Film Transistor) or the like identified as a circuit element is formed on the glass substrate to which is attached the single crystal semiconductor device identified as a circuit element. By electrically connecting the TFT and the like with the MOS transistor and the like provided at the single crystal semiconductor device, an integrated circuit is obtained. Thus, an active matrix type semiconductor device suitable for use in display devices such as a liquid crystal display device and organic electroluminescence display device is formed.

The MOS transistor or the like included in the single crystal semiconductor device set forth above is employed as an active element constituting a microcontroller, a D/A (Digital/Analog) converter, an amplifier, a timing generator, a DSP (Digital Signal Processor), and the like. The TFT or the like formed on the glass substrate is employed as an active element constituting a pixel transistor, a source driver, a gate driver, and the like.

### CITATION LIST

### Patent Literature

PTL 1: Japanese Patent Laying-Open No. 2008-66566

PTL 2: Japanese Patent Laying-Open No. 2008-147445

### Non-Patent Literature

Non-Patent Literature 1: Electronics Letters, Vol. 31, No. 14, 1995, p. 1201

Non-Patent Literature 2: JJAP, Vol. 36, 1997, p. 1636

### SUMMARY OF INVENTION

### Technical Problem

When a single crystal semiconductor device is to be attached to the surface of a glass substrate, the surface roughness of respective attaching faces must be rendered as small as possible such that the glass substrate and the single crystal semiconductor device will be attached with sufficient binding force through van der Waals' force and hydrogen bonding strength. However, an oxide film formed by CVD (Chemical Vapor Deposition) is not suitable for the aforementioned attaching since its as-formed surface roughness is great.

Therefore, the single crystal semiconductor device must have the surface of the oxide film that was obtained by CVD planarized through CMP to achieve a surface roughness suitable for attaching. On part of the glass substrate, it is extremely difficult to planarize the surface of the oxide film formed by CVD by means of CMP since the size of the CMP device currently available is not sufficiently large enough. Accordingly, it is preferable to use the surface of the glass serving as the substrate per se for the attaching face.

Thus, in order to obtain a semiconductor device set forth above, the best condition for attaching is to use the surface of an oxide film planarized by CMP as the attaching face on part of the single crystal semiconductor device and to use the exposed surface of glass itself as the attaching face on part of the glass substrate, and joining these faces together to achieve binding between the single crystal semiconductor device and glass substrate.

Furthermore, in order to obtain the semiconductor device set forth above, accurate positioning of the single crystal semiconductor device on the glass substrate for attaching is indispensable. If this positioning is not performed sufficiently, electrical connection with the circuit elements such as TFT formed on the glass substrate subsequently will become difficult, leading to significant degradation in the yield.

Positioning in the field of semiconductor devices is generally carried out by providing alignment marks at the members that are to be positioned, and setting the position of the members such that the alignment marks overlap each other. In the case where such positioning is to be applied to the semiconductor device set forth above, an alignment mark will be formed in advance at the glass substrate, and another alignment mark will be formed at the single crystal semiconductor device, followed by positioning the glass substrate and the single crystal semiconductor device such that the alignment marks overlap each other.

In consideration of the attaching face of the glass substrate being the surface of the exposed glass per se as mentioned above to ensure the above-described favorable attaching condition, any two of the positioning methods set forth below may be employed.

The first method is directed to forming a recess at the surface of the glass substrate, which will be used as an alignment mark. In the case where this first method is employed, the position of the glass substrate and single crystal semiconductor device is adjusted such that the recess serving as an alignment mark formed in advance at the surface of the glass substrate and the alignment mark formed in advance at the single crystal semiconductor device overlap each other. Thus, positioning of the glass substrate and single crystal semiconductor device is performed.

The second method is directed to forming a film serving as an alignment mark at a portion of the surface of the glass substrate. In the case where the second method is employed, an etching stopped film is provided on the glass substrate to protect the surface. A film constituting an alignment mark and various films for forming a TFT and the like are deposited on the etching stopper film. Then, various films formed on the glass substrate located at the region where a single crystal semiconductor device is to be attached are removed using the etching stopper film. A relevant portion of the etching stopper film is removed to expose an area of the glass substrate surface. Then, the position of the glass substrate and the single crystal semiconductor device is adjusted such that the film remaining on the glass substrate, serving as an alignment mark, and the alignment mark formed in advance at the single crystal semiconductor device overlap each other. Thus, the positioning of the glass substrate and single crystal semiconductor device is performed.

The aforementioned first method is disadvantageous in that a photography step and etching step will be additionally required in order to form a recess serving as an alignment mark at the surface of the glass substrate. The second method is similarly disadvantageous in that a photography step and etching step are additionally required since an etching stopper film is to be formed on the glass substrate, and a portion of the etching stopper film is to be removed subsequently.

Since additional steps to form an alignment mark are required in the event of any of the first and second methods, there will be a problem that the fabrication process is rendered complex and the fabrication cost will be increased. For example, in the case where a TFT of the bottom gate structure is to be formed on the glass substrate, the required number of photolithography steps is appropriately 5 times. In the case where such a TFT is to be formed while employing the first or second method, the required number of photolithography steps will be increased to appropriately 6-7 times. The ratio of increase in the steps and fabrication cost will become extremely high.

The present invention is directed to solving the above-described problems. An object of the present invention is to provide a method of fabricating a semiconductor device formed of an integrated circuit, readily and economically, by electrical connection of a single crystal semiconductor device identified as a circuit element attached on a substrate and a structure identified as a circuit element formed on the substrate. Another object of the present invention is to provide a semiconductor device that can be fabricated readily and economically according to the method of fabricating a semiconductor device.

### Solution to Problem

A method of fabricating a semiconductor device according to the present invention includes the steps of forming a single crystal semiconductor device identified as a circuit element, attaching the single crystal semiconductor device at a predetermined position on a substrate, forming a structure identified as a circuit element differing from the single crystal semiconductor device at a predetermined position on the substrate to which the single crystal semiconductor device is attached, and forming an integrated circuit by electrically connecting the single crystal semiconductor device and the structure identified as circuit elements. In the step of forming a single crystal semiconductor device, an alignment mark is provided at the single crystal semiconductor device. In the step of attaching a single crystal semiconductor device, the single crystal semiconductor device is positioned and attached on the substrate based on mechanical accuracy of an attachment device that attaches the single crystal semiconductor device relative to the substrate. In the step of forming a structure, the structure is positioned and formed on the substrate based on the alignment mark provided at the single crystal semiconductor device.

In the method of fabricating a semiconductor device according to the present invention, the step of forming a single crystal semiconductor device includes the steps of forming a single crystal semiconductor element on one main face of a single crystal semiconductor substrate, thinning the single crystal semiconductor substrate by removing a portion of the single crystal semiconductor substrate from the other main face along the thickness direction, forming an alignment mark at a predetermined position of an exposed face side that has been exposed by thinning the single crystal semiconductor substrate, and forming a planarized film for attaching at the exposed face side of the single crystal semiconductor substrate such that the alignment mark is covered.

In the method of fabricating a semiconductor device according to the present invention, the alignment mark is formed using a portion of a film deposited to form the single crystal semiconductor element at the single crystal semiconductor device.

In the method of fabricating a semiconductor device according to the present invention, the film constituting the alignment mark includes at least one selected from the group consisting of silicon, polysilicon, amorphous silicon, aluminum, molybdenum, tungsten, titanium, titanium nitride, copper, silver, gold and tantalum, as a material.

In the method of fabricating a semiconductor device according to the present invention, the semiconductor included in the single crystal semiconductor device includes at least one selected from the group consisting of a single crystal silicon semiconductor, group IV semiconductor, group II-VI compound semiconductor, group III-V compound semiconductor, group IV-IV compound semiconductor, mixed crystal including a congener element thereof, and oxide semiconductor.

In the method of fabricating a semiconductor device according to the present invention, the substrate is a glass substrate.

In the method of fabricating a semiconductor device according to the present invention, the structure is a TFT.

In the method of fabricating a semiconductor device according to the present invention, the single crystal semiconductor device includes any of an NMOS transistor or a PMOS transistor.

In the method of fabricating a semiconductor device according to the present invention, the single crystal semiconductor device includes an NMOS transistor and a PMOS transistor.

The semiconductor device according to the present invention is fabricated according to any of the above-described methods of fabricating a semiconductor device.

### Advantageous Effects of Invention

According to the present invention, a semiconductor device formed of an integrated circuit can be fabricated readily and economically by electrical connection of a single crystal semiconductor device identified as a circuit element attached on a substrate and a structure identified as a circuit element formed on the substrate.

### BRIEF DESCRIPTION OF DRAWINGS

FIG. 1 is a schematic sectional view to describe a method of fabricating a semiconductor device according to an embodiment of the present invention.

FIG. 2 is a schematic sectional view for describing a method of fabricating a semiconductor device according to an embodiment of the present invention.

FIG. 3 is a schematic sectional view for describing a method of fabricating a semiconductor device according to an embodiment of the present invention.

FIG. 4 is a schematic sectional view for describing a method of fabricating a semiconductor device according to an embodiment of the present invention.

FIG. 5 is a schematic sectional view for describing a method of fabricating a semiconductor device according to an embodiment of the present invention.

FIG. 6 is a schematic sectional view for describing a method of fabricating a semiconductor device according to an embodiment of the present invention.

FIG. 7 is a schematic sectional view for describing a method of fabricating a semiconductor device according to an embodiment of the present invention.

FIG. 8 is a schematic sectional view for describing a method of fabricating a semiconductor device according to an embodiment of the present invention.

FIG. 9 is a schematic sectional view for describing a method of fabricating a semiconductor device according to an embodiment of the present invention.

FIG. 10 is a schematic sectional view for describing a method of fabricating a semiconductor device according to an embodiment of the present invention.

FIG. 11 is a schematic sectional view for describing a method of fabricating a semiconductor device according to an embodiment of the present invention.

FIG. 12 is a schematic sectional view for describing a method of fabricating a semiconductor device according to an embodiment of the present invention.

FIG. 13 is a schematic sectional view for describing a method of fabricating a semiconductor device according to an embodiment of the present invention.

FIG. 14 is a schematic sectional view for describing a method of fabricating a semiconductor device according to an embodiment of the present invention.

FIG. 15 is a schematic sectional view for describing a method of fabricating a semiconductor device according to an embodiment of the present invention.

FIG. 16 is a schematic sectional view for describing a method of fabricating a semiconductor device according to an embodiment of the present invention.

FIG. 17 is a schematic sectional view for describing a method of fabricating a semiconductor device according to an embodiment of the present invention.

FIG. 18 is a schematic sectional view for describing a method of fabricating a semiconductor device according to an embodiment of the present invention.

FIG. 19 is a schematic sectional view for describing a method of fabricating a semiconductor device according to an embodiment of the present invention.

FIG. 20 is a schematic sectional view for describing a method of fabricating a semiconductor device according to an embodiment of the present invention.

FIG. 21 is a schematic sectional view for describing a method of fabricating a semiconductor device according to an embodiment of the present invention.

FIG. 22 is a schematic sectional view for describing a method of fabricating a semiconductor device according to an embodiment of the present invention.

FIG. 23 is a schematic sectional view for describing a method of fabricating a semiconductor device according to an embodiment of the present invention.

FIG. 24 is a schematic sectional view for describing a method of fabricating a semiconductor device according to an embodiment of the present invention.

FIG. 25 is a schematic sectional view for describing a method of fabricating a semiconductor device according to an embodiment of the present invention.

FIG. 26 is a schematic sectional view for describing a method of fabricating a semiconductor device according to an embodiment of the present invention.

FIG. 27 is a schematic sectional view for describing a method of fabricating a semiconductor device according to an embodiment of the present invention.

FIG. 28A is a plan view schematically representing a method of fabricating an additional substrate used in the method of fabricating a semiconductor device according to an embodiment of the present invention.

FIG. 28B is a sectional view schematically representing a method of fabricating an additional substrate used in the method of fabricating a semiconductor device according to an embodiment of the present invention.

FIG. 29A is a plan view schematically representing a fabrication method and configuration of an additional substrate used in the method of fabricating a semiconductor device according to an embodiment of the present invention.

FIG. 29B is a sectional view schematically representing a fabrication method and configuration of an additional substrate used in the method of fabricating a semiconductor device according to an embodiment of the present invention.

FIG. 30 is a schematic plan view representing a manner of a single crystal semiconductor device attached to a substrate in the method of fabricating a semiconductor device according to an embodiment of the present invention.

### DESCRIPTION OF EMBODIMENTS

An embodiment of the present invention will be described in detail with reference to the drawings. The embodiment will be described based on an example of the present invention applied to an active matrix type semiconductor device suitable for use in a liquid crystal display device, organic electroluminescence display device, and the like. The single crystal semiconductor device that is to be attached will be described based on an example including a CMOS transistor as a single crystal semiconductor element.

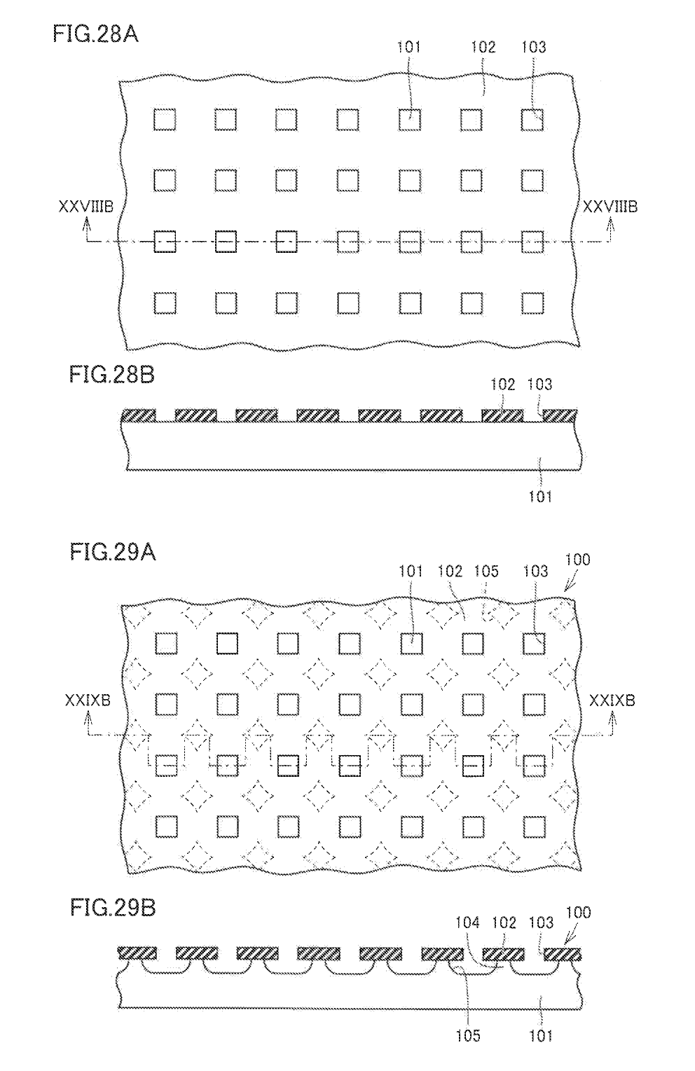

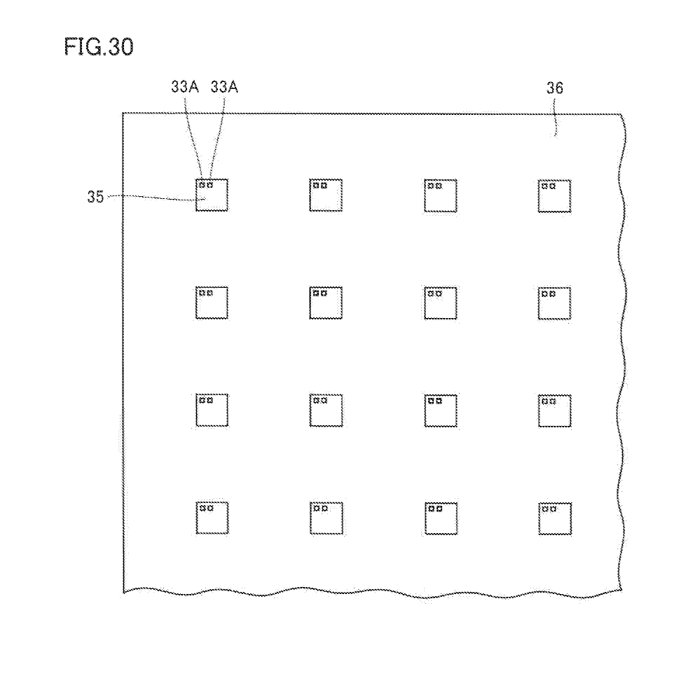

FIGS. 1-27 are schematic sectional views for describing a method of fabricating a semiconductor device according to an embodiment of the present invention. FIGS. 28A, 28B, 29A and 29B are plan views and sectional views schematically representing a fabrication method and configuration of an additional substrate employed in the method of fabricating a semiconductor device according to the present invention. FIG. 30 is a schematic plan view representing a manner of a single crystal semiconductor device attached to a substrate in the method of fabricating a semiconductor device according to the embodiment.

In the method of fabricating a semiconductor device according to the present embodiment shown in FIG. 1, first a silicon substrate 1 is prepared as a single crystal semiconductor substrate. Silicon substrate 1 is subjected to thermal treatment in an oxygen atmosphere to form a thermal oxide film 2 of approximately 30 nm, for example, in thickness on the main surface of silicon substrate 1. Thermal oxide film 2 serves to prevent the main surface of silicon substrate 1 from being contaminated during an ion implantation step that will be described afterwards. Formation of thermal oxide film 2 is dispensable, as the case may be.

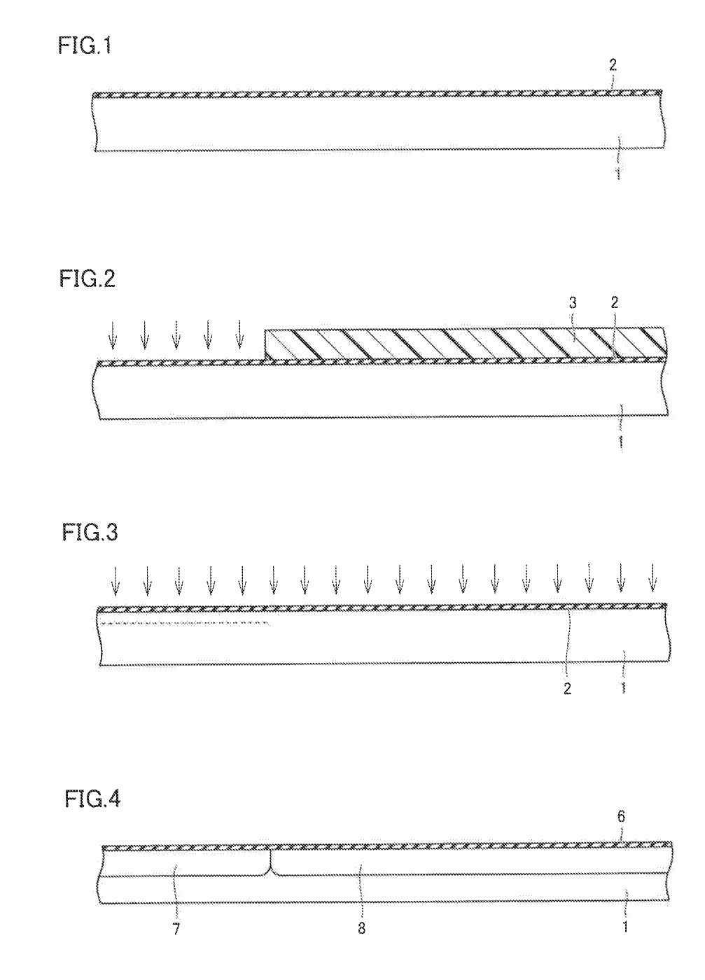

As shown in FIG. 2, a resist film 3 is formed partially on thermal oxide film 2. An N type impurity element is introduced by ion implantation into an N well formation region of silicon substrate 1 at a region corresponding to an opening region of resist film 3. For the impurity element, phosphorous, for example is employed. The implantation energy is set at approximately 50 KeV to 150 KeV. The dosage thereof is set at approximately 1×10¹²cm⁻² to 1×10¹³cm⁻². In the case where a P type impurity element is to be implanted all over the main surface of silicon substrate 1 at a subsequent step, the dosage is set with an additional N type impurity element in consideration of the amount canceled by the P type impurity element.

As shown in FIG. 3, following removal of resist film 3, a P type impurity element is implanted by ion implantation all over the entire surface of silicon substrate 1. As the impurity element, boron, for example is employed. The implantation energy thereof is set at approximately 10 KeV to 50 KeV. The dosage thereof is set at approximately 1×10¹²cm⁻² to 1×10¹³cm⁻². Since the thermal diffusion coefficient of phosphorus in silicon substrate 1 is smaller than that of boron, thermal treatment may be carried out prior to introduction of boron to appropriately diffuse phosphorus in advance into silicon substrate 1. Furthermore, in the case where canceling of the N type impurity element caused by the P type impurity element at the N well formation region is to be avoided, the main surface of silicon substrate 1 at the region corresponding to the N well formation region may be covered with a resist film prior to implantation of a P type impurity element, and then introduce the P type impurity element by ion implantation into a P well formation region of silicon substrate 1 at the region corresponding to the opening region of the resist film. In this case, the aforementioned canceling by the P type impurity element does not have to be taken into consideration in the implantation of the N type impurity element into the N well formation region.

As shown in FIG. 4, following removal of thermal oxide film 2, thermal treatment at approximately 900° C. to 1000° C. is applied in an oxygen atmosphere to form a thermal oxide film 6 of approximately 30 nm in thickness, for example, on the main surface of silicon substrate 1. This thermal treatment causes diffusion of the impurity element implanted into the N well formation region and P well formation region to form an N well region 7 and a P well region 8 extending from the main surface of silicon substrate 1 in the thickness direction.

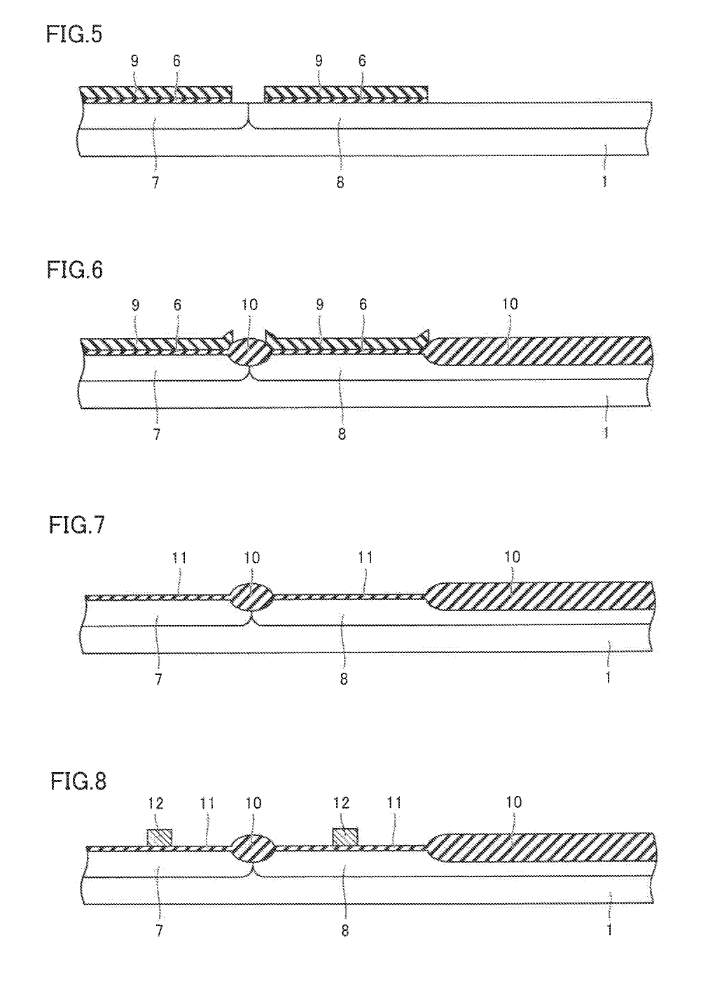

As shown in FIG. 5, following formation of a silicon nitride film 9 on thermal oxide film 6 through CVD, thermal oxide film 6 and silicon nitride film 9 are partially removed. Thus, thermal oxide film 6 and silicon nitride film 9 are patterned.

Referring to FIG. 6, thermal treatment at approximately 900° C. to 1000° C. is applied in an oxygen atmosphere to effect LOCOS (Local Oxidation of Silicon) to form an isolation film 10 of approximately 200 nm-500 nm. Isolation film 10 formed is an element isolation film to isolate the activation region of silicon substrate 1. Alternatively, an element isolation film may be formed by employing the STI (Shallow Trench Isolation) technique instead of LOCOS.

As shown in FIG. 7, following removal of thermal oxide film 6 and silicon nitride film 9, thermal treatment at approximately 1000° C. is applied in an oxygen atmosphere to form a gate oxide film 11 identified as a gate insulation film. The thickness of gate oxide film 11 is preferably, but not particularly limited to approximately 10 nm-20 nm A gate insulation film may be provided, instead of gate oxide film 11, by depositing an insulation film other than an oxide film. In order to adjust the threshold voltage of the MOS transistor to be formed, an N type impurity element or a P type impurity element may be introduced by ion implantation into the NMOS transistor formation region and/or PMOS transistor formation region after removal of silicon nitride film 9.

As shown in FIG. 8, polysilicon is deposited by CVD, which is patterned by partial removal to form a gate electrode 12 on gate oxide film 11 at the region corresponding to the NMOS transistor formation region and PMOS transistor formation region. The thickness of gate electrode 12 is preferably, but not particularly limited to approximately 300 nm

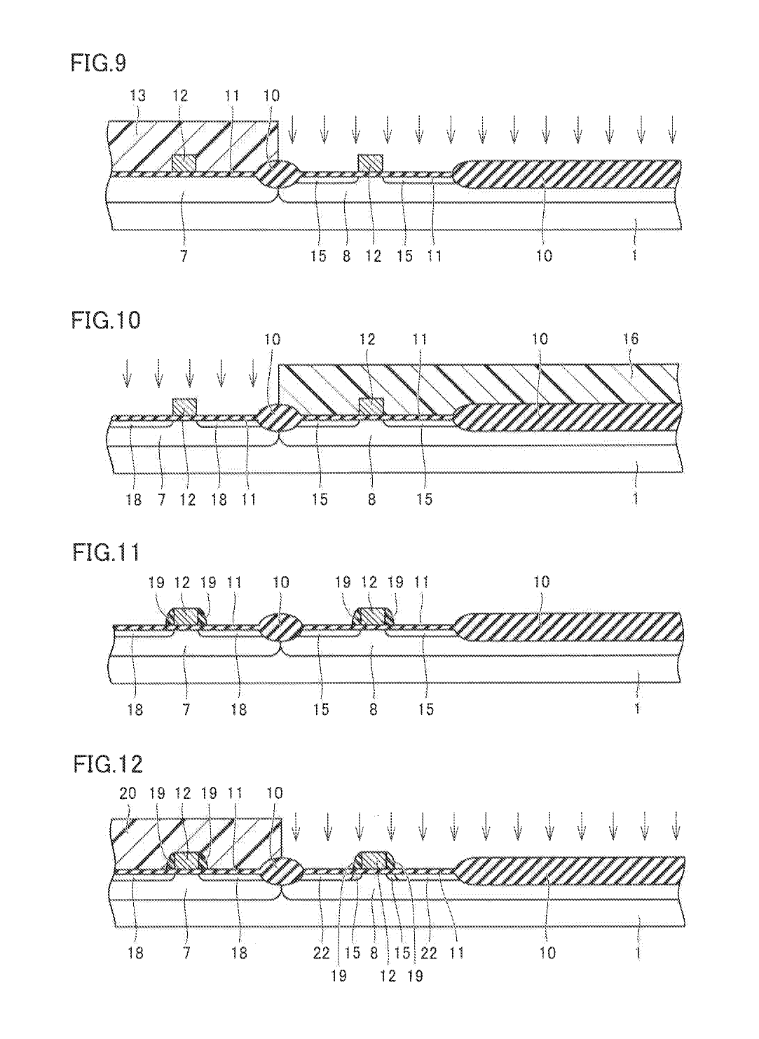

As shown in FIG. 9, a resist film 13 is formed such that the region corresponding to the NMOS transistor formation region is open in order to provide an LDD (Light Doped Drain) region at the NMOS transistor formation region of silicon substrate 1. An N type impurity element is introduced into the NMOS transistor formation region by ion implantation using gate electrode 12 as a mask. Accordingly, an N type low concentration impurity region 15 is formed at the NMOS transistor formation region of silicon substrate 1. Here, phosphorus, for example, is employed as the impurity element. The dosage thereof is set at approximately 5×10¹²cm⁻²-5×10¹³cm⁻². At this stage, oblique ion implantation (HALO implantation) directed to suppressing the short channel effect may be carried out.

As shown in FIG. 10, following removal of resist film 13, a resist film 16 is formed such that the region corresponding to the PMOS transistor formation region is open in order to provide an LDD region at the PMOS transistor formation region of silicon substrate 1. A P type impurity element is introduced into the PMOS transistor formation region by ion implantation using gate electrode 12 as a mask. Thus, a P type low concentration impurity region 18 is formed at the PMOS transistor formation region of silicon substrate 1. Here, boron, for example, is employed as the impurity element. The dosage thereof is set at approximately 5×10¹²cm⁻²-5×10¹³cm⁻². At this stage, oblique ion implantation (HALO implantation) directed to suppressing the short channel effect may be carried out. It is to be noted that boron has a large thermal diffusion coefficient in silicon substrate 1. In the case where P type low concentration impurity region 18 of the PMOS transistor can be formed through just the thermal diffusion of boron introduced by the P type high concentration impurity implantation towards the PMOS transistor formation region in a subsequent step, the above-described P type impurity element implantation for forming an LDD region may not necessary have to be carried out.

Referring to FIG. 11, following removal of resist film 16, a silicon oxide film is deposited by CVD. The silicon oxide film is subjected to anisotropic dry etching to form sidewall film 19 at both sidewalls of gate electrode 12.

As shown in FIG. 12, a resist film 20 is formed such that the NMOS transistor formation region is open. Using gate electrode 12 and sidewall film 19 as a mask, an N type impurity element is introduced into the NMOS transistor formation region by ion implantation. Accordingly, an N type high concentration impurity region 22 is formed at the NMOS transistor formation region of silicon substrate 1. Here, phosphorus, for example, is employed as the impurity element.

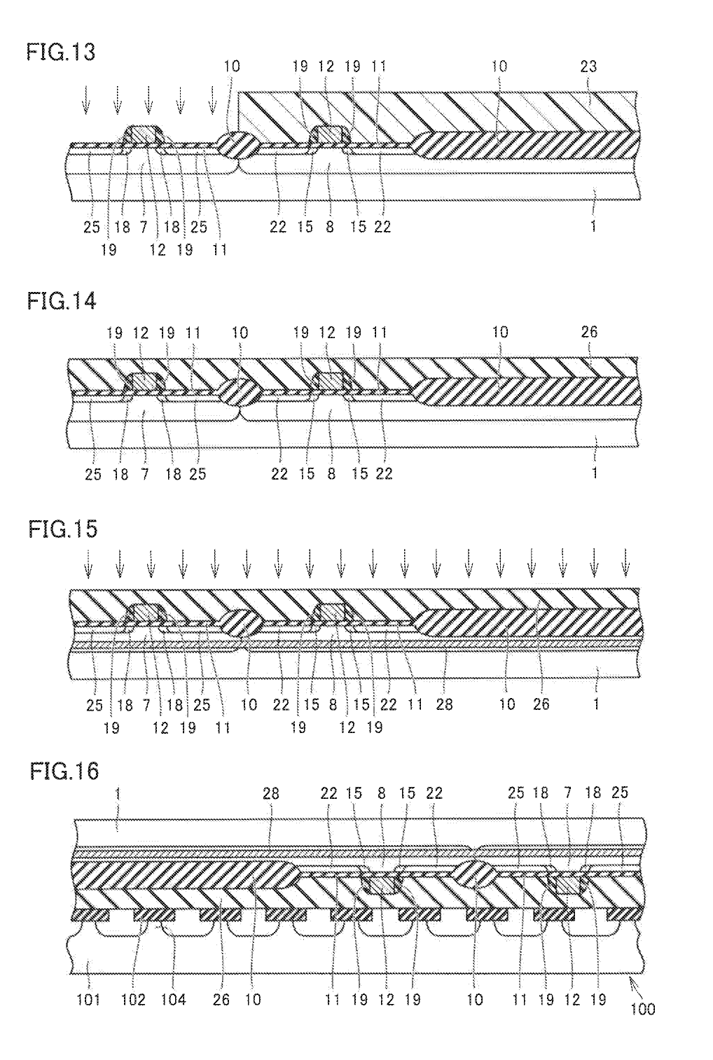

Referring to FIG. 13, following removal of resist film 20, a resist film 23 is formed such that the PMOS transistor formation region is open. Using gate electrode 12 and sidewall film 19 as a mask, a P type impurity element is introduced into the PMOS transistor formation region by ion implantation. Thus, a P type high concentration impurity region 25 is formed at the PMOS transistor formation region of silicon substrate 1. Here, boron, for example, is employed as the impurity element. Then, resist film 23 is removed. Thermal activation treatment is carried out to render active the impurity element that has been ion-implanted. For this thermal activation treatment, thermal treatment at 900° C. for approximately 10 minutes is preferable.

As shown in FIG. 14, an insulation film such as a silicon oxide film is deposited by CVD. The insulation film is planarized by CMP to form a planarized film 26. Planarized film 26 is formed to entirely cover the main surface side of silicon substrate 1.

As shown in FIG. 15, a peel-off substance including at least one type of hydrogen or an inactive element (for example, helium, neon, or the like) is introduced into silicon substrate 1 by ion implantation to form a peel-off substance introduced layer 28. The implantation conditions will be set forth below. In the case where hydrogen is employed as the peel-off substance, the dosage thereof is set at approximately 2×10¹⁶cm⁻² to 1×10¹⁷cm⁻². The implantation energy thereof is set at approximately 100 KeV to 200 KeV. The position of peel-off substance introduced layer 28 formed at silicon substrate 1 is preferably located deeper than the impurity regions of the NMOS transistor and PMOS transistor, and at a depth within the range of the region where N well region 7 and P well region 8 are located.

Thus, fabrication of a single crystal semiconductor device including a CMOS transistor with an NMOS transistor and a PMOS transistor as single crystal semiconductor elements is temporarily completed.

As shown in FIG. 16, the single crystal semiconductor device temporarily completed in fabrication is attached to an additional substrate 100. As additional substrate 100, a silicon substrate 101 having a thermal oxide film 102 formed at the tip of a columnar support 104 is employed.

Before describing the attaching process of the single crystal semiconductor device to the additional substrate, a method of forming the additional substrate and its configuration will be described with reference to FIGS. 28A, 28B, 29A and 29B. FIGS. 28A and 29A are schematic plan views of an additional substrate. FIG. 28B is a schematic sectional view of the additional substrate taken along line XXVIIIB-XXVIIIB shown in FIG. 28A. FIG. 29B is a schematic sectional view of the additional substrate taken along line XXIXB-XXIXB shown in FIG. 29A.

In the fabrication of an additional substrate 100 as shown in FIGS. 28A and 28B, first a silicon substrate 101 is prepared. Silicon substrate 101 is subjected to thermal treatment in an oxygen atmosphere to form a thermal oxide film 102 of approximately 100 nm-300 nm in thickness, for example, on the main surface of silicon substrate 101. Then, thermal oxide film 102 is partially removed by photolithography to form square openings 103, each that is approximately 0.5 μm at one side, in a plurality of arrays in thermal oxide film 102 at the pitch of approximately 1.5 μm.

As shown in FIGS. 29A and 29B, silicon substrate 101 is selectively etched using an appropriate etching gas (for example, XeF₂) until the aforementioned columnar support 104 is formed on silicon substrate 101. Accordingly, additional substrate 100 is provided, including an isolation structure 105 formed by the partial removal of silicon substrate 101, and thermal oxide film 102 formed at the tip of columnar support 104. Although the above description is based on the case where isolation structure 105 is obtained by dry etching, isolation structure 105 may be obtained by wet etching using an alkali solution such as of TMAH (tetra methyl ammonium hydroxide). The diameter and height of columnar support 104 are preferably optimized appropriately so as to withstand the subsequent CMP process and to allow separation by the stress of additional substrate 100.

In the attaching process of the single crystal semiconductor device temporarily completed in fabrication to the additional substrate as shown in FIG. 16, the single crystal semiconductor device is attached to additional substrate 100 so as to achieve binding between planarized film 26 of the single crystal semiconductor device and thermal oxide film 102 of additional substrate 100. Before this attaching process, a hydrophilization process such as an SC1 process in which the surfaces of planarized film 26 and thermal oxide film 102 are dipped in an ammonia hydrogen peroxide solution is carried out.

Then, in order to improve the binding of the single crystal semiconductor device relative to additional substrate 100, thermal treatment is carried out for approximately two hours at approximately 200° C.-300° C. Accordingly, the attaching process of a single crystal semiconductor device temporarily completed in fabrication to an additional substrate 100 is completed.

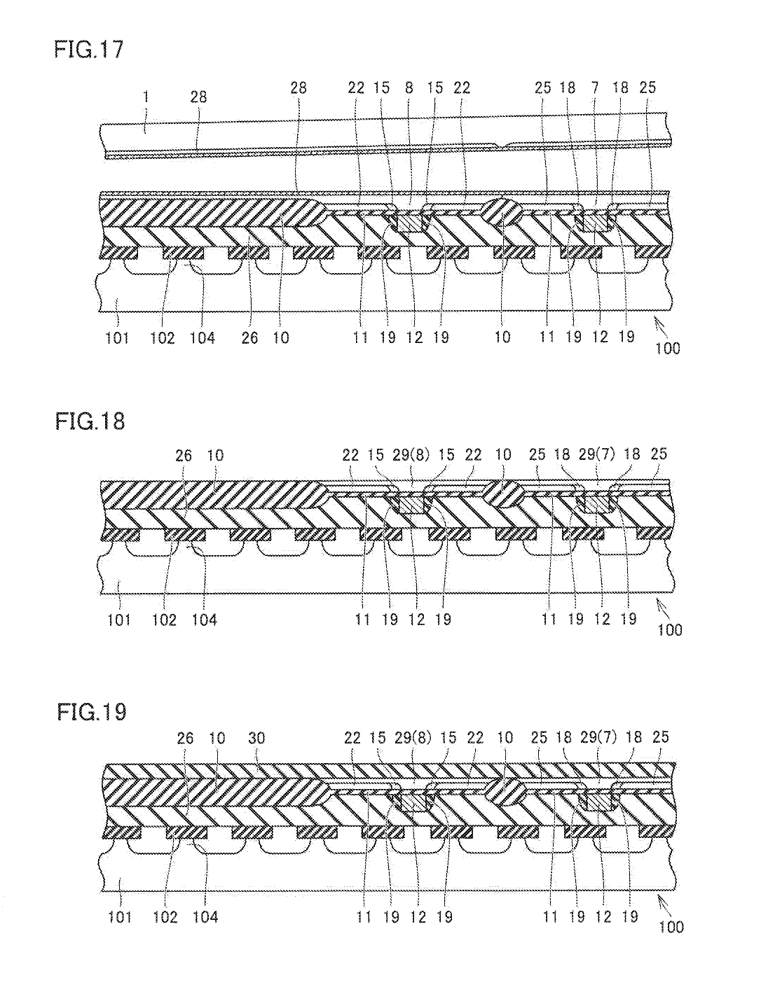

As shown in FIG. 17, the single crystal semiconductor device is heated to approximately 400° C.-600° C. By separating and removing a portion of silicon substrate 1 along peel-off substance introduced layer 28 formed at silicon substrate 1 of the single crystal semiconductor device, silicon substrate 1 is thinned. Accordingly, a single crystal semiconductor device having silicon substrate 1 thinned is transferred to additional substrate 100.

As shown in FIG. 18, the remainder of peel-off substance introduced layer 28 adhering to silicon substrate 1 of the single crystal semiconductor device is removed by polishing, etching or the like. Silicon substrate 1 is further thinned by polishing, etching, or the like until isolation film 10 is exposed. Accordingly, silicon substrate 1 is taken as single crystal silicon thin film 29, and complete element isolation of the NMOS transistor and PMOS transistor can be performed.

As shown in FIG. 19, a protection insulation film 30 to protect the surface of single crystal silicon thin film 29 is formed. For protection insulation film 30, a silicon oxide film deposited through CVD can be employed. The thickness thereof is 100 nm, for example. Then, thermal treatment is carried out for 10 seconds to 2 hours at 600° C.-800° C. to remove the peel-off substance such as hydrogen included in single crystal silicon thin film 29 as well as the thermal donor or lattice defect. Since reactivation of P type impurities is allowed at this thermal treatment, improving the reproducibility of the CMOS transistor characteristics and stabilization of the CMOS transistor characteristics are allowed. The thermal treatment temperature in the thermal treatment is preferably less than or equal to 850° C. to avoid disturbing the impurity profile of the CMOS transistor.

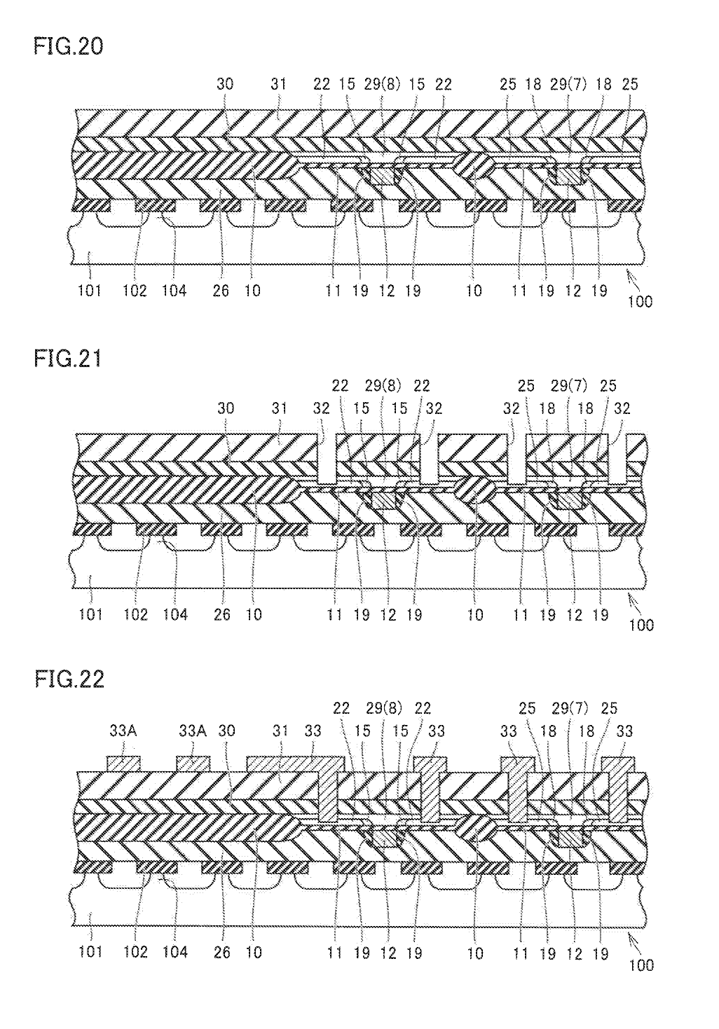

As shown in FIG. 20, an interlayer insulation film 31 is formed to ensure sufficient wiring capacitance so as to avoid influencing the property of the CMOS transistor. For this interlayer insulation film 31, a silicon oxide film deposited by CVD and the like can be used.

As shown in FIG. 21, interlayer insulation film 31 and protection insulation film 30 are etched to form a contact hole 32. Each contact hole 32 is formed so as to reach N type high concentration impurity region 22 constituting source/drain regions of the NMOS transistor, and P type high concentration impurity region 25 constituting source/drain regions of the PMOS transistor. More preferably, each contact hole 32 is made to arrive further deeper than the surface of single crystal silicon thin film 29. Accordingly, the connection resistance between a contact that will be formed subsequently and single crystal silicon thin film 29 can be reduced more reliably and stably. In the actual etching process, the surface of single crystal silicon thin film 29 is to be exposed under an etching condition having a high selective ratio of protection insulation film 30 to single crystal silicon thin film 29, and then single crystal silicon thin film 29 is to be etched taking into consideration the distance from the surface to the high concentration impurity region in the depth direction.

As shown in FIG. 22, a metal interconnection film is deposited so as fill at least contact hole 32 and cover the surface of interlayer insulation film 31, followed by partial removal for patterning. Thus, an interconnection layer 33 including a contact and an alignment mark 33A are formed. Preferably at this stage, titanium and titanium nitride are deposited for the barrier metal, and aluminum-copper of low resistance is deposited for the metal interconnection film. Since thermal treatment at high temperature is not required in subsequent steps, aluminum-silicon, aluminum-copper, copper or the like can be used for the metal interconnection film. Furthermore, in the case where the diameter of contact hole 32 is less than or equal to 0.5 μm, a metal interconnection film such as of aluminum may be formed after tungsten is deposited as the buried plug contact.

Alignment mark 33A is a positioning mark used in a subsequent step of forming a TFT and the like. Alignment mark 33A is formed at a predetermined position on interlayer insulation film 31 above isolation film 10 where a CMOS transistor, for example, is not formed. This alignment mark 33A has an outer shape of approximately several hundred μm in plan view, considerably large as compared to the size of the CMOS transistor. For the sake of convenience, alignment mark 33A and the CMOS transistor are depicted as having comparable size in the drawings.

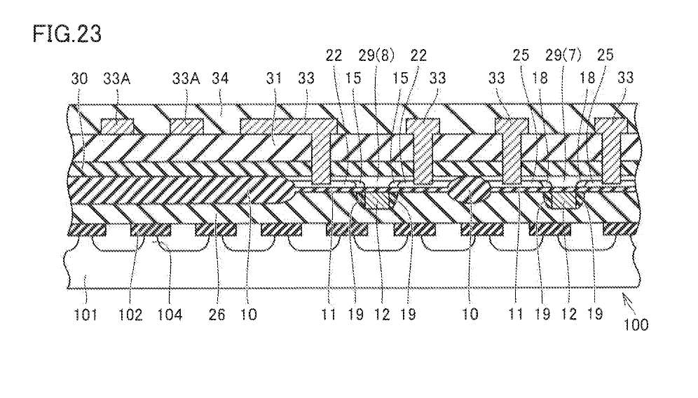

As shown in FIG. 23, a silicon oxide film is deposited using a mixture gas of TEOS (Tetraethoxysilane) and oxygen by PECVD (Plasma Enhanced CVD) or the like so as to cover interconnection layer 33 and alignment mark 33A. The silicon oxide film is planarized by CMP or the like to form a planarized film 34.

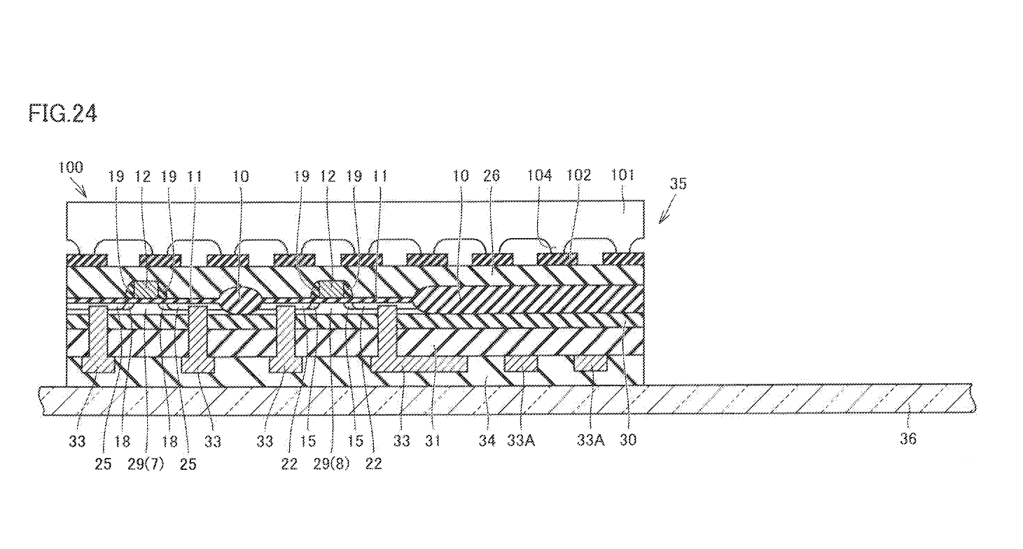

Thus, a method of fabricating a single crystal semiconductor device including a CMOS transistor with an NMOS transistor and a PMOS transistor as single crystal semiconductor elements, and further having an interconnection layer 33 connected to the CMOS transistor and an alignment mark 33A is completed. After fabrication of a single crystal semiconductor device set forth above is completed, the single crystal semiconductor device and additional substrate 100 to which the single crystal semiconductor device is attached are diced into individual pieces, separated as a plurality of dies 35 (refer to FIG. 24).

As shown in FIG. 24, each piece of die 35 is attached to glass substrate 36 that is a substrate. As glass substrate 36 to which die 35 is attached, a substrate made of glass as the base material, having a flat main surface and exposed at the main surface, is employed. Glass substrate 36 is completely absent of an alignment mark formed by providing a recess at its main surface, an alignment mark formed by depositing a film on the main surface, or the like.

As shown in FIG. 30, a plurality of separate pieces of dies 35 are attached to the main surface of glass substrate 36 in an array having a predetermined distance between each other. For this attaching process, an attachment device not shown is employed. For example, the attachment device includes a stage for holding glass substrate 36 by suction through the mounting of glass substrate 36, a drive mechanism for driving the stage in translation biaxially (X-axis direction and Y-axis direction), and a feed mechanism for supplying each piece of die 35 on the main surface of glass substrate 36 mounted on the stage. The attachment device drives the drive mechanism to move glass substrate 36 held in suction on the stage at a predetermined interval within a plane including the X axis and Y axis to deliver die 35 each time onto glass substrate 36 by driving the feed mechanism. Accordingly, die 35 including a single crystal semiconductor device is positioned and attached on glass substrate 36 based on the mechanical accuracy of the attachment device. By using a linear motor for the driving mechanism, the positioning accuracy may become as high as 0.1 μm, allowing die 35 to be positioned and attached to glass substrate 36 at high accuracy. Furthermore, for the feed mechanism, a collet or the like that allows die 35 to be held by suction may be used.

As shown in FIG. 24, in the attaching process of die 35 to glass substrate 36, the single crystal semiconductor device is attached relative to glass substrate 36 to achieve binding between planarized film 34 of the single crystal semiconductor device and the main surface of glass substrate 36. At this stage, attachment is conducted such that alignment mark 33A provided at the single crystal semiconductor device can be read above glass substrate 36. Prior to this attaching process, a hydrophilization process such as an SC1 process in which the surfaces of planarized film 34 and glass substrate 36 are dipped in an ammonia hydrogen peroxide solution is carried out.

In order to couple die 35 to glass substrate 36 with favorable binding, the average surface roughness Ra of planarized film 34 and glass substrate 36 is preferably set less than or equal to 0.3 nm (preferably, less than or equal to 0.2 nm). For the purpose of increasing the binding force, die 35 and glass substrate 36 that will be coupled by the van der Waals' force and hydrogen bonding strength is subjected to thermal treatment at approximately 400° C.-600° C. to cause a dehydration reaction (that is, —Si—OH+—Si—OH→—Si—O—Si—+H₂) to achieve strong bonding of atoms with each other. In the case where interconnection layer 33 is formed of a metal material of low resistance, this thermal treatment is preferably carried out at a lower temperature. Thus, the attaching process of die 35 including a single crystal semiconductor device with glass substrate 36 is completed.

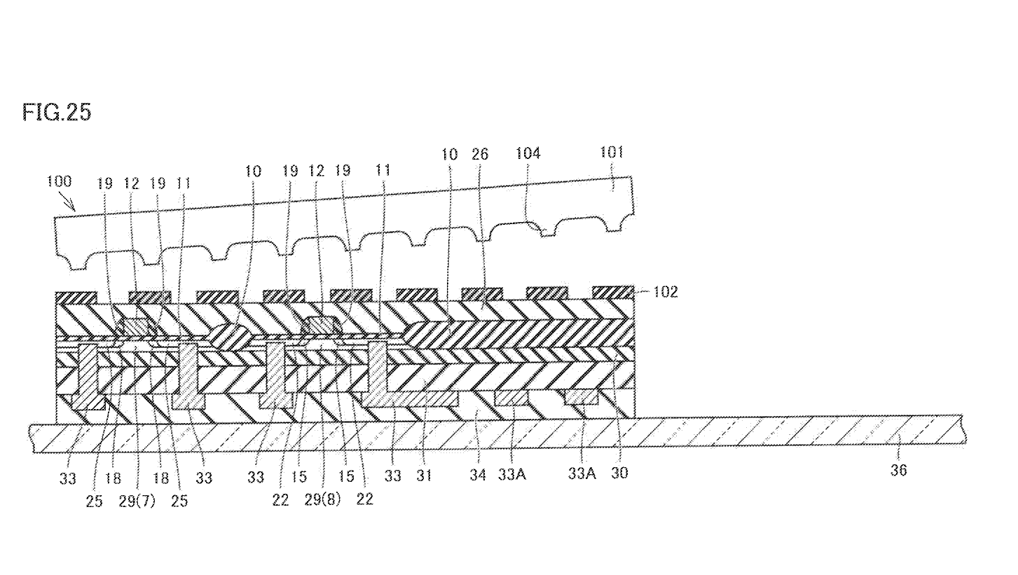

As shown in FIG. 25, external force such by as twisting, lateral sliding, peeling off or the like is imposed at additional substrate 100 with die 35 to apply stress in the proximity of support 104 and thermal oxide film 102 of additional substrate 100 to cause cleavage, whereby mainly silicon substrate 101 of additional substrate 100 is separated and removed from the single crystal semiconductor device. Accordingly, a thinned single crystal semiconductor device is transferred to glass substrate 36.

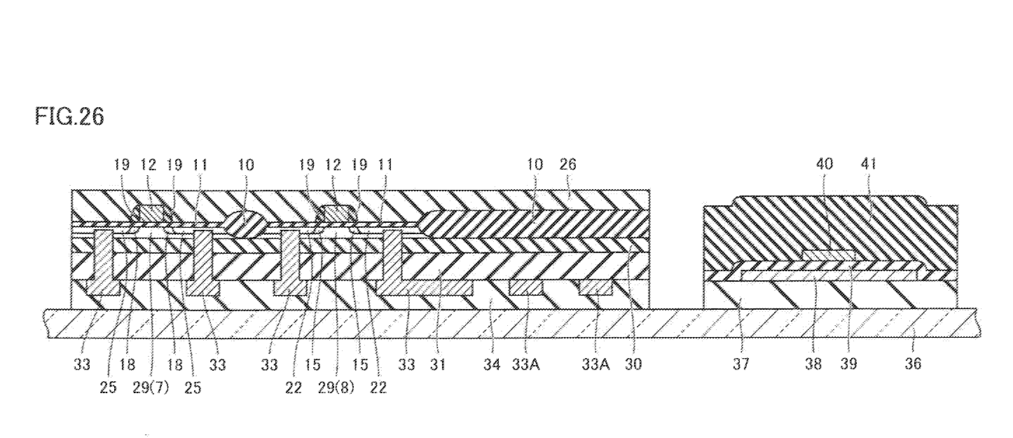

As shown in FIG. 26, the remainder of additional substrate 100 adhering to the single crystal semiconductor device (i.e. a portion of thermal oxide film 102 and support 104) is removed by etching or the like to form a TFT that is a structure identified as a circuit element at a predetermined position on glass substrate 36. Specifically, by sequentially patterning and depositing an underlying insulation film 37, a thin film semiconductor layer 38 such as of polysilicon or amorphous silicon, a gate insulation film 39, a gate electrode 40, and an interlayer insulation film 41 on glass substrate 36, a TFT is formed on glass substrate 36.

In the formation of a TFT, the TFT is positioned in place on glass substrate 36 based on alignment mark 33A provided in the single crystal semiconductor device. More specifically, in the patterning of the above-described various films constituting a TFT, the positioning of the mask for patterning is performed with alignment mark 33A provided in the single crystal semiconductor device as a reference. Thus, a TFT to be formed will be positioned at high accuracy in place on glass substrate 36. Accordingly, the relative position accuracy between the single crystal semiconductor device and the TFT identified as circuit elements will be ensured. Electrical connection of these circuit elements at a subsequent interconnection process can be carried out reliably.

Since only thin insulation films such as interlayer insulation film 31, protection insulation film 30, isolation film 10, and planarized film 26 are present above alignment mark 33A, reading of alignment mark 33A during the formation of a TFT set forth above is allowed through these thin insulation films from the main surface side of glass substrate 36 (i.e. the side to which the semiconductor device is attached). Therefore, alignment mark 33A does not have to be read out from the backside of glass substrate 36 employing a highly transmitting light such as an infrared ray, independent of the thickness of glass substrate 36 or the like, and allowing usage of light of a short wavelength. Thus, positioning can be carried out at high frequency.

In view of the patterning accuracy of each type of film on glass substrate 36 generally being 1 μm-3 μm and the positioning accuracy of attaching the single crystal semiconductor device in the event of using the above-described attachment device being approximately 0.1 μm, the relevant attaching position accuracy is sufficiently smaller than the patterning accuracy. Thus, the TFT alignment above glass substrate 36 is carried out at sufficient high accuracy.

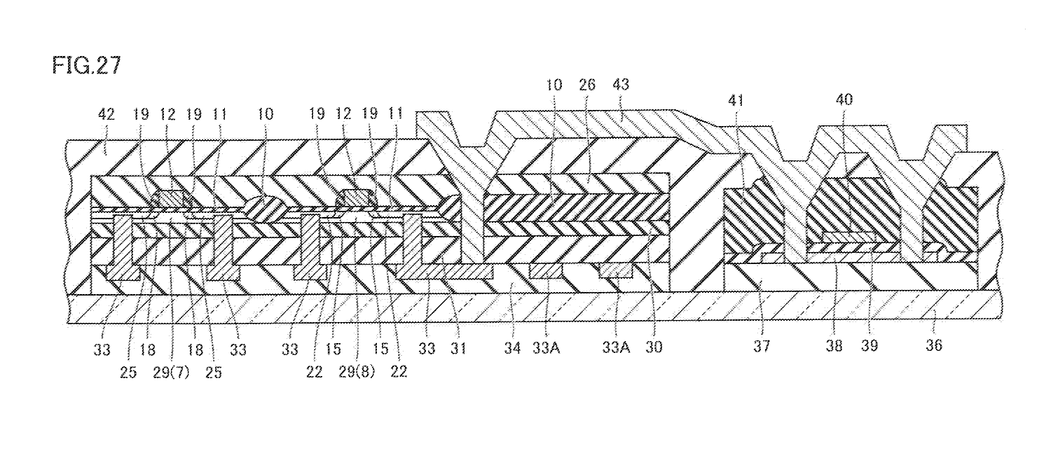

As shown in FIG. 27, a silicon oxide film is deposited using a mixture gas of TEOS and oxygen by PECVD so as to cover the single crystal semiconductor device and TFT located on glass substrate 36. The silicon oxide film is planarized by CMP or the like to form a planarized film 42. Then, a contact hole is formed by etching in planarized film 42, planarized film 26 and the like of the single crystal semiconductor device, interlayer insulation film 41 of the TFT, and the like. A metal interconnection film such as of aluminum is deposited so as to fill the formed contact hole and cover the surface of planarized film 42. The metal interconnection film is partially removed for patterning to form an interconnection layer 43 including a contact. Accordingly, an integrated circuit is formed on glass substrate 36 having the single crystal semiconductor device and TFT electrically connected by interconnection layer 43. Thus, fabrication of a semiconductor device is completed.

The characteristic features in the method of fabricating a semiconductor device according to the present embodiment will be summarized in the following. The method of fabricating a semiconductor device according to the present embodiment includes the steps of forming a single crystal semiconductor device identified as a circuit element (refer to FIGS. 1-23 and the like), attaching the single crystal semiconductor device at a predetermined position on a glass substrate 36 identified as a substrate (refer to FIGS. 24, 25, 30 and the like), forming a TFT that is a structure identified as a circuit element differing from the single crystal semiconductor device at a predetermined position on glass substrate 36 to which the single crystal semiconductor device is attached (refer to FIG. 26 and the like), and forming an integrated circuit by electrically connecting the single crystal semiconductor device and the TFT identified as circuit elements (refer to FIG. 27 and the like). In the step of forming a single crystal semiconductor device (refer to FIGS. 1-23 and the like), an alignment mark 33A is provided at the single crystal semiconductor device (particularly, refer to FIG. 22). In the step of attaching a single crystal semiconductor device (refer to FIGS. 24, 25, 30 and the like), the single crystal semiconductor device is positioned and attached on glass substrate 36 based on the machining accuracy of an attachment device that attaches the single crystal semiconductor device relative to glass substrate 36 (refer particularly to FIG. 30). In the step of forming a TFT (refer to FIG. 26 and the like), the TFT is positioned and formed on glass substrate 36 based on alignment mark 33A provided at the single crystal semiconductor device (refer particularly to FIG. 26).

By employing the method of fabricating a semiconductor device according to the present embodiment set forth above, a single crystal semiconductor device is positioned at high accuracy to be attached on glass substrate 36, and a TFT is positioned at high accuracy to be formed on glass substrate 36 relative to the single crystal semiconductor device attached on glass substrate 36. Accordingly, electrical connection of the single crystal semiconductor device with the TFT can be performed reliably, leading to drastic improvement in the yield. Furthermore, by employing the method of fabricating a semiconductor device according to the present embodiment set forth above, it is not required to provide a recess serving as an alignment mark at the main surface of glass substrate 36, or to form a film serving as an alignment mark on the main surface of glass substrate 36. Therefore, the additional photolithography step and etching step are dispensable. The problem of the fabrication step rendered complicated or increased in the fabrication cost will not occur.

By fabricating a semiconductor device based on the method of fabricating a semiconductor device of the present embodiment, a semiconductor device formed of an integrated circuit by electrical connection between a single crystal semiconductor device identified as a circuit element attached on glass substrate 36 and a TFT identified as a circuit element formed on glass substrate 36 can be fabricated readily and economically. As a result, an active matrix type semiconductor device of high performance can be fabricated readily and economically.

Although the present embodiment has been described based on an example in which a single crystal semiconductor device including a CMOS transistor with an NMOS transistor and an PMOS transistor as single crystal semiconductor elements is produced, the single crystal semiconductor element formed in the single crystal semiconductor device may be one of an NMOS transistor and PMOS transistor, or may be another semiconductor device such as a diode or a thyristor bipolar transistor.

The present embodiment has been described based on an example in which a metal film deposited during formation of an interconnection layer is employed as the alignment mark provided at the single crystal semiconductor device. Additionally, instead of a metal film, a film including materials such as silicon, polysilicon, amorphous silicon, aluminum, molybdenum, tungsten, titanium, titanium nitride, copper, sulfur, gold and tantalum may be employed as the alignment mark. Regardless of which material is employed, an additional photolithography step or etching step is not required by forming an alignment mark utilizing a portion of the film deposited for the formation of a single crystal semiconductor element provided at the single crystal semiconductor device. An alignment mark can be formed readily and economically.

The present embodiment has been described based on an example utilizing a silicon substrate as the base material in forming a single crystal semiconductor device. For this base material substrate, a single crystal semiconductor substrate including at least one of a single crystal silicon semiconductor, group IV semiconductor, group II-VI compound semiconductor, group III-V compound semiconductor, group IV-IV compound semiconductor, mixed crystal including a congener element thereof, and oxide semiconductor may be employed.

The present embodiment has been described based on an example utilizing a glass substrate for the substrate to which a single crystal semiconductor device is attached. Additionally, instead of a glass substrate, various types including an insulative substrate such as a plastic substrate, a metal substrate such as of stainless steel covered with a silicon oxide film or/and silicon nitride film can be used. Particularly, in the case where an active matrix type semiconductor device employed an organic electroluminescence display device is to be fabricated, an insulation covered metal plate superior in shock resistance is preferably used since the substrate does not require transparency. In the case where a plastic substrate is employed for the substrate, the single crystal semiconductor device and plastic substrate may be attached by an adhesive or the like.

Although the present embodiment has been described based on an example in which the structure formed on the substrate is a bottom gate structure TFT, a TFT of another structure, or an element other than a TFT, may be the structure formed on the substrate.

Although the present embodiment is described based on an example in which the present invention is applied to an active matrix type semiconductor device suitable for use in a liquid crystal display device or an organic electroluminescence display device, the present invention is applicable to a semiconductor device of other types.

Thus the embodiments disclosed herein are illustrative and non-restrictive in every respect. The technical scope of the present invention is defined by the terms of the claims, and is intended to include any modification within the scope and meaning equivalent to the terms of the appended claims.

### REFERENCE SIGNS LIST

1 silicon substrate; 2 thermal oxide film; 3 resist film; 6 thermal oxide film; 7 N well region; 8 P well region; 9 silicon nitride film; 10 isolation film; 11 gate oxide film; 12 gate electrode; 13 resist film; 15 N type low concentration impurity region; 16 resist film; 18 P type low concentration impurity region; 19 sidewall film; 20 resist film; 22 N type high concentration impurity region; 23 resist film; 25 P type high concentration impurity region; 26 planarized film; 28 peel-off substance introduced layer; 29 single crystal silicon thin film; 30 protection insulation film; 31 interlayer insulation film; 32 contact hole; 33 interconnection layer; 33A alignment mark; 34 planarized film; 35 die; 36 glass substrate; 37 underlying insulation film; 38 thin film semiconductor layer; 39 gate insulation film; 40 gate electrode; 41 interlayer insulation film; 42 planarized film; 43 interconnection layer; 100 additional substrate; 101 silicon substrate; 102 thermal oxide film; 103 opening; 104 support; 105 isolation structure.

1. A method of fabricating a semiconductor device comprising the steps of:
forming a single crystal semiconductor device identified as a circuit element,
attaching said single crystal semiconductor device at a predetermined position on a substrate,
forming a structure identified as a circuit element differing from said single crystal semiconductor device at a predetermined position on said substrate to which said single crystal semiconductor device is attached, and
forming an integrated circuit by electrically connecting said single crystal semiconductor device and said structure identified as circuit elements, wherein
in said step of forming a single crystal semiconductor device, an alignment mark is provided at said single crystal semiconductor device,
in said step of attaching a single crystal semiconductor device, said single crystal semiconductor device is positioned and attached on said substrate based on machining accuracy of an attachment device that attaches said single crystal semiconductor device relative to said substrate, and
in said step of forming a structure, said structure is positioned and formed on said substrate based on said alignment mark provided at said single crystal semiconductor device.

2. The method of fabricating a semiconductor device according to claim 1, wherein said step of forming a single crystal semiconductor device comprises the steps of
forming a single crystal semiconductor element at one main face of a single crystal semiconductor substrate,
thinning said single crystal semiconductor substrate by removing a portion of said single crystal semiconductor substrate from the other main face of said single crystal semiconductor substrate along a thickness direction,
forming said alignment mark at a predetermined position of an exposed face side that has been exposed by thinning said single crystal semiconductor substrate, and
forming a planarized film for attaching at said exposed face side of said single crystal semiconductor substrate such that said alignment mark is covered.

3. The method of fabricating a semiconductor device according to claim 2, wherein said alignment mark is formed using a portion of a film deposited to form said single crystal semiconductor element at said single crystal semiconductor device.

4. The method of fabricating a semiconductor device according to claim 3, wherein said film constituting said alignment mark includes at least one selected from the group consisting of silicon, polysilicon, amorphous silicon, aluminum, molybdenum, tungsten, titanium, titanium nitride, copper, silver, gold and tantalum, as a material.

5. The method of fabricating a semiconductor device according to claim 1, wherein the semiconductor included in said single crystal semiconductor device includes at least one selected from the group consisting of a single crystal silicon semiconductor, group IV semiconductor, group II-VI compound semiconductor, group III-V compound semiconductor, group IV-IV compound semiconductor, mixed crystal including a congener element thereof, and oxide semiconductor.

6. The method of fabricating a semiconductor device according to claim 1, wherein said substrate is a glass substrate.

7. The method of fabricating a semiconductor device according to claim 1, wherein said structure is a TFT.

8. The method of fabricating a semiconductor device according to claim 1, wherein said single crystal semiconductor device includes any of an NMOS transistor or a PMOS transistor.

9. The method of fabricating a semiconductor device according to claim 1, wherein said single crystal semiconductor device includes an NMOS transistor and a PMOS transistor.

10. A semiconductor device fabricated according to the method of fabricating a semiconductor device defined in claim 1.
